(19) United States
(12) Patent Application Publication
(10) Pub. No.: US 2026/0144146 A1
(43) Pub. Date: May 21, 2026

(54) SEMICONDUCTOR DEVICE

(71) Applicant: Samsung Electronics Co., Ltd., Suwon-si (KR)

(72) Inventors: Junkyoung LEE, Suwon-si (KR); Jubin SEO, Suwon-si (KR); Ho-Jin LEE, Suwon-si (KR); Dong-Chan LIM, Suwon-si (KR); Joo Hee JANG, Suwon-si (KR)

(21) Appl. No.: 19/191,062

(22) Filed: Apr. 28, 2025

(30) Foreign Application Priority Data
Nov. 19, 2024 (KR) 10-2024-0164942

(51) Int. Cl. H01L 23/00; H01L 25/07

(52) U.S. Cl. CPC H10W 90/00; H10W 72/923; H10W 72/934; H10W 72/942; H10W 72/952; H10W 80/732; H10W 90/26; H10W 90/297; H10W 90/792

(57) ABSTRACT

A semiconductor device may include a first bonding pad having a first width, and a second bonding pad coupled to the first bonding pad and having a second width different from the first width, wherein the first bonding pad includes a first material, and the second bonding pad includes a second material different from the first material.

### CROSS-REFERENCE TO RELATED APPLICATIONS

This application claims priority to Korean Patent Application No. 10-2024-0164942, filed in the Korean Intellectual Property Office on Nov. 19, 2024, the entire contents of which are hereby incorporated by reference.

### BACKGROUND OF THE INVENTION

### Field of the Invention

The present disclosure relates to a semiconductor device, and a method of forming thereof.

### Description of Related Art

Demand for high capacity, thinning, and miniaturization of semiconductor devices and electronic products using the same is increasing in the semiconductor industry, and various packaging technologies related to this are continuously emerging. One example is a packaging technology that can implement high-density chip stacking by vertically stacking various semiconductor chips. This technology has the advantage that it is possible to integrate semiconductor chips with various functions into a smaller area than a typical package formed of one semiconductor chip.

Meanwhile, a hybrid copper bonding method is applied for bonding between semiconductors when stacking multiple semiconductor chips vertically. The semiconductor chips are miniaturized and the difficulty of the process of forming copper pads used in the bonding process increases. Accordingly, research is being conducted to improve the reliability of hybrid copper bonding.

### SUMMARY OF THE INVENTION

In order to address one or more problems (e.g., the problems described above and/or other problems not explicitly described herein), the present disclosure provides a semiconductor device with improved electrical characteristics and reliability, and a method of forming the semiconductor device.

According to some embodiments of the present disclosure, in the semiconductor device, a first bonding pad is formed with a greater width than the width of a second bonding pad, thereby facilitating the bonding of the first bonding pad to the second bonding pad. Accordingly, the reliability of the semiconductor device can be improved.

According to some embodiments of the present disclosure, in the semiconductor device, the second bonding pad includes a different material than the first bonding pad, allowing the second bonding pad to be formed with a high aspect ratio. As a result, the second bonding pad can be formed with a smaller width than the width of the first bonding pad, and the integration density and reliability of the semiconductor device can be improved.

According to some embodiments of the present disclosure, a semiconductor device may include a first bonding pad having a first width, and a second bonding pad in contact with the first bonding pad and having a second width different from the first width, wherein the first bonding pad includes a first material, and the second bonding pad includes a second material different from the first material.

According to some embodiments of the present disclosure, a semiconductor device may include a first sub-device including a first circuit layer and a first bonding pad disposed on the first circuit layer, and a second sub-device disposed on the first sub-device and including a second circuit layer and a second bonding pad electrically connected to the first bonding pad, wherein the first bonding pad includes a first material, and the second bonding pad includes a second material different from the first material.

According to some embodiments of the present disclosure, a semiconductor device may include a first sub-device including a first circuit layer, a first connection wiring electrically connected to the first circuit layer, and a first bonding pad electrically connected to the first connection wiring, and a second sub-device electrically connected to the first sub-device, wherein the second sub-device includes a second circuit layer, a second connection wiring electrically connected to the second circuit layer, and a second bonding pad electrically connected to the second connection wiring and electrically connected to the first bonding pad, the first bonding pad includes a first material, the second bonding pad includes a second material different from the first material, a width of the first bonding pad is greater than a width of the second bonding pad, and the width of the second bonding pad is less than a height of the second bonding pad.

### BRIEF DESCRIPTION OF THE DRAWINGS

The above and other embodiments and features of the present invention will become more apparent by describing in detail example embodiments thereof with reference to the attached drawings, in which:

FIG. 1 is a diagram illustrating a semiconductor substrate in which semiconductor devices are integrated according to some embodiments;

FIG. 2 is a cross-sectional view provided to explain a semiconductor device according to some embodiments;

FIG. 3 is an enlarged view provided to explain a region Q1 of FIG. 2;

FIG. 4 is a diagram provided to explain a semiconductor device according to some embodiments;

FIG. 5 is a diagram provided to explain a semiconductor device according to some embodiments;

FIG. 6 is a diagram provided to explain a semiconductor device according to some embodiments;

FIG. 7 is a diagram provided to explain a semiconductor device according to some embodiments;

FIG. 8 is a diagram provided to explain a semiconductor device according to some embodiments;

FIG. 9 is a diagram provided to explain a semiconductor device according to some embodiments;

FIG. 10 is a diagram provided to explain a semiconductor device according to some embodiments;

FIG. 11 is an enlarged view provided to explain a region Q2 of FIG. 10;

FIG. 12 is a diagram provided to explain a semiconductor device according to some embodiments;

FIG. 13 is an enlarged view provided to explain a region Q3 of FIG. 12;

FIGS. 14 and 15 are diagrams provided to explain a semiconductor device according to some embodiments; and

FIG. 16 is a flow diagram of an example of a method of forming a semiconductor device according to an embodiment of the invention.

### DETAILED DESCRIPTION

In the present disclosure, ordinal numbers such as first, second, etc. may be used to describe various devices or components, but the devices or components are not limited by these terms. It should be understood that unless the context indicates otherwise, these terms are only used to distinguish one element or component from another element or component. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

Items described in the singular herein may be provided in plural, as can be seen, for example, in the drawings. Thus, the description of a single item that is provided in plural should be understood to be applicable to the remaining plurality of items unless context indicates otherwise.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

A semiconductor device according to some embodiments will be described in detail with reference to the drawings.

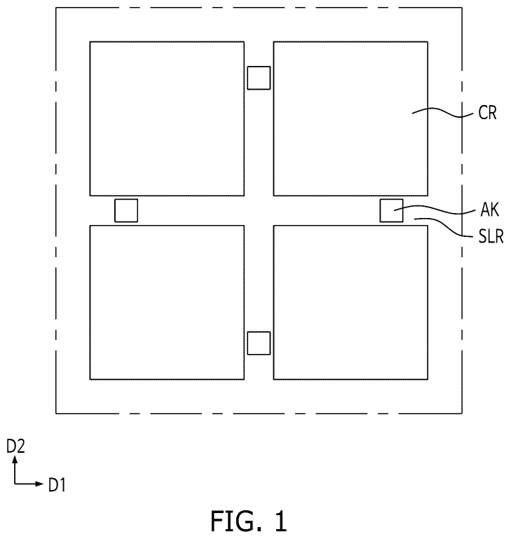

FIG. 1 is a diagram illustrating a semiconductor substrate in which semiconductor devices are integrated according to some embodiments.

Referring to FIG. 1, the semiconductor substrate may include a plurality of chip regions CR in which semiconductor chips are formed, and a scribe line region SLR disposed between the plurality of chip regions CR. For example, the semiconductor substrate may be a wafer, a portion of which is shown in FIG. 1. The chip regions CR may be two-dimensionally arranged in first and second directions D1 and D2 intersecting each other. Each of the chip regions CR may be surrounded by the scribe line region SLR. For example, the scribe line region SLR may be disposed between the chip regions CR adjacent to each other in the first direction D1 and between the chip regions CR adjacent to each other in the second direction D2. Circuit structures to be described below may be disposed in the chip regions CR.

An alignment key AK may be disposed in the scribe line region SLR. For example, alignment keys AK may be disposed around the chip region CR. The alignment key AK may be used to couple (or align) a semiconductor substrate to another semiconductor substrate. For example, a first circuit structure and a first alignment key may be formed on a first semiconductor substrate, and a second circuit structure and a second alignment key may be formed on a second semiconductor substrate. The first semiconductor substrate and the second semiconductor substrate may be aligned using the first alignment key and the second alignment key, and the first circuit structure and the second circuit structure may be bonded to each other.

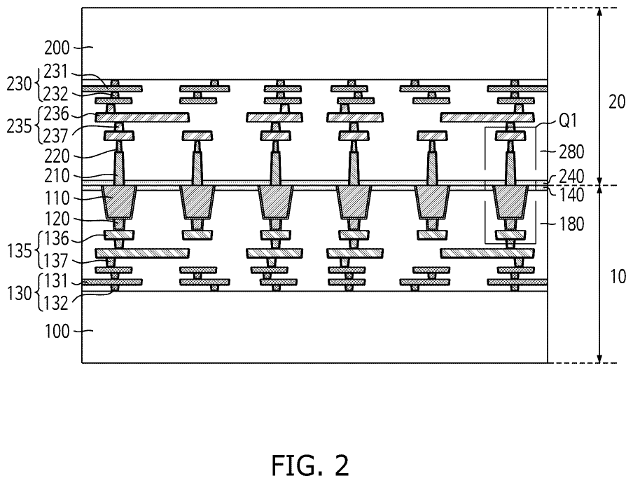

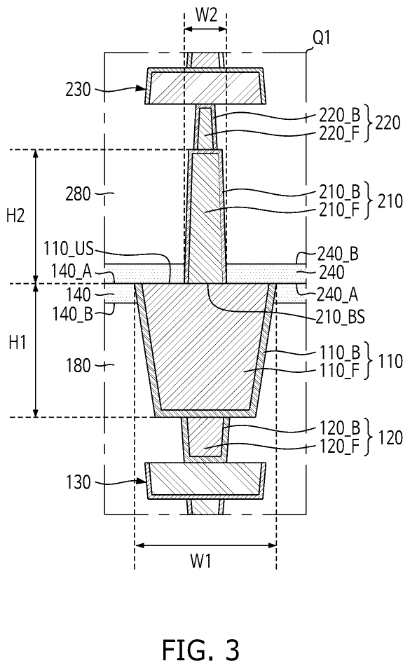

FIG. 2 is a cross-sectional view provided to explain a semiconductor device according to some embodiments. FIG. 3 is an enlarged view provided to explain a region Q1 of FIG. 2.

Referring to FIGS. 2 and 3, the semiconductor device according to some embodiments may include a first circuit structure 10 and a second circuit structure 20. For example, each of the first circuit structure 10 and the second circuit structure 20 may be a portion of a corresponding one of semiconductor substrates (or wafers).

The first circuit structure 10 may include a first circuit device 100, a first lower interconnect structure 130, a second lower interconnect structure 135, a first via 120, a first bonding pad 110, a lower interlayer insulating film 180, and a first bonding insulating layer 140.

The first lower interconnect structure 130 may be disposed in the lower interlayer insulating film 180. The first lower interconnect structure 130 may be disposed on the first circuit device 100. The first lower interconnect structure 130 may be electrically connected to the first circuit device 100. The integrated circuits of the first circuit device 100 and the first lower interconnect structure 130 may be electrically connected to each other.

As used herein, components described as being “electrically connected” are configured such that an electrical signal can be transferred from one component to the other (although such electrical signal may be attenuated in strength as it is transferred and may be selectively transferred). Further, when components are electrically connected, it may also include the components being connected directly or indirectly through another conductive component.

The first lower interconnect structure 130 may include a first lower interconnect layer 131 and a first lower via 132 connected to the first lower interconnect layer 131. The first lower interconnect layer 131 may extend in one direction. For example, the first lower interconnect layer 131 may extend in a horizontal direction. The horizontal direction may be a direction perpendicular to the direction in which the first circuit structure 10 and the second circuit structure 20 are stacked. The first lower via 132 may be disposed between the first lower interconnect layers 131. Each of the first lower interconnect layer 131 and the first lower via 132 may include a conductive material. The number of stacked first lower interconnect layers 131 may vary.

The second lower interconnect structure 135 may be disposed in the lower interlayer insulating film 180. The second lower interconnect structure 135 may be disposed on the first lower interconnect structure 130. The second lower interconnect structure 135 may be electrically connected to the first lower interconnect structure 130.

The second lower interconnect structure 135 may include a second lower interconnect layer 136 and a second lower via 137 to be connected to the second lower interconnect layer 136. The second lower interconnect layer 136 may extend in one direction. The second lower interconnect layer 136 may extend in the same direction as the first lower interconnect layer 131. However, the invention is not limited to the above. The second lower via 137 may be disposed between the second lower interconnect layers 136. Each of the second lower interconnect layer 136 and the second lower via 137 may include a conductive material. The number of stacked second lower interconnect layers 136 may vary.

In some embodiments, the thickness of the first lower interconnect layer 131 and the thickness of the second lower interconnect layer 136 may be different from each other. For example, the thickness of the first lower interconnect layer 131 may be less than the thickness of the second lower interconnect layer 136. However, the invention is not limited to the above. The thickness of the first lower interconnect layer 131 may be the same as the thickness of the second lower interconnect layer 136.

The first via 120 may be disposed on the second lower interconnect structure 135. For example, the first via 120 may be disposed on the second lower interconnect layer 136. The first via 120 may be electrically connected to the second lower interconnect structure 135. The first bonding pad 110 may be disposed on the first via 120. The first via 120 may electrically connect the first bonding pad 110 to the second lower interconnect structure 135.

The second circuit structure 20 may include a second circuit device 200, a first upper interconnect structure 230, a second upper interconnect structure 235, a second via 220, a second bonding pad 210, an upper interlayer insulating film 280, and a second bonding insulating layer 240.

The first upper interconnect structure 230 may be disposed in the upper interlayer insulating film 280. The first upper interconnect structure 230 may be disposed on the second circuit device 200. The first upper interconnect structure 230 may be electrically connected to the second circuit device 200. For example, the first upper interconnect structure 230 may be electrically connected to integrated circuits of the second circuit device 200.

The first upper interconnect structure 230 may include a first upper interconnect layer 231 and a first upper via 232 connected to the first upper interconnect layer 231. The first upper interconnect layer 231 may extend in one direction. For example, the first upper interconnect layer 231 may extend in a horizontal direction. The first upper via 232 may be disposed between the first upper interconnect layers 231. Each of the first upper interconnect layer 231 and the first upper via 232 may include a conductive material. The number of stacked first upper interconnect layers 231 may vary.

The second upper interconnect structure 235 may be disposed in the upper interlayer insulating film 280. The second upper interconnect structure 235 may be disposed on the first upper interconnect structure 230. The second upper interconnect structure 235 may be electrically connected to the first upper interconnect structure 230.

The second upper interconnect structure 235 may include a second upper interconnect layer 236 and a second upper via 237 to be connected to the second upper interconnect layer 236. The second upper interconnect layer 236 may extend in one direction. The second upper interconnect layer 236 may extend in the same direction as the first upper interconnect layer 231. However, the invention is not limited to the above. The second upper via 237 may be disposed between the second upper interconnect layers 236. Each of the second upper interconnect layer 236 and the second upper via 237 may include a conductive material. The number of stacked second upper interconnect layers 236 may vary.

In some embodiments, the thickness of the first upper interconnect layer 231 and the thickness of the second upper interconnect layer 236 may be different from each other. For example, the thickness of the first upper interconnect layer 231 may be less than the thickness of the second upper interconnect layer 236. However, the invention is not limited to the above. The thickness of the first upper interconnect layer 231 may be the same as the thickness of the second upper interconnect layer 236.

Each of the lower interlayer insulating film 180 and the upper interlayer insulating film 280 may include at least one of, for example, silicon oxide (SiO), silicon nitride (SiN), silicon oxynitride (SiON), and a low-k material. For example, the low-k material may include fluorinated tetraethylorthosilicate (FTEOS), hydrogen silsesquioxane (HSQ), bis-benzocyclobutene (BCB), tetramethylorthosilicate (TMOS), octamethyleyclotetrasiloxane (OMCTS), hexamethyldisiloxane (HMDS), trimethylsilyl borate (TMSB), diacetoxyditertiarybutosiloxane (DADBS), trimethylsilil phosphate (TMSP), polytetrafluoroethylene (PTFE), tonen silazen (TOSZ), fluoride silicate glass (FSG), polyimide nanofoams such as polypropylene oxide, carbon doped silicon oxide (CDO), organo silicate glass (OSG), SiLK, amorphous fluorinated carbon, silica aerogels, silica xerogels, mesoporous silica, or a combination thereof. However, the invention is not limited to the above.

The second via 220 may be disposed on the second upper interconnect structure 235. For example, the second via 220 may be disposed on the second upper interconnect layer 236. The second via 220 may be electrically connected to the second upper interconnect structure 235. The second bonding pad 210 may be disposed on the second via 220. The second via 220 may electrically connect between the second bonding pad 210 and the second upper interconnect structure 235.

The second bonding pad 210 may be disposed on the second via 220. The second bonding pad 210 may be disposed in the upper interlayer insulating film 280. The upper interlayer insulating film 280 and the second bonding insulating layer 240 may surround the second bonding pad 210.

Each of the circuit devices 100 and 200 may be a circuit layer. For example, each of the circuit layers 100 and 200 may include a combination of individual devices (e.g., transistors, diodes, resistors, capacitors, etc.) and conductive wires. The conductive wires may interconnect the individual devices. For example, the circuit devices 100 and 200 may include or be circuit components such as memory cells, logic circuits (e.g., a logic gate, such as a NAND, OR, XOR, NOT (an inverter), NAND, NOR, or an XNOR gate), image pixels, MEMS (Micro-Electro-Mechanical Systems), etc., or a part of each of the circuit components, but the present invention is not limited thereto.

Each of the interconnect structures 130, 135, 230 and 235 may be a connection wiring. For example, each of the interconnect structures may be a combination of conductive patterns (or layers) and conductive vias, and may constitute a part of the electrical connection between the first circuit structure 10 and the second circuit structure 20.

Each of the circuit structures 10 and 20 may be a sub-device, which include the circuit layers 100 and 200. For example, the sub-devices 10 and 20 may be electrically connected to each other through the connection wirings 130, 135, 230 and 235, thereby forming a semiconductor device.

Hereinbelow, the first bonding pad 110 and the second bonding pad 210, and the configurations surrounding the same will be described in detail with reference to FIG. 3.

The first bonding pad 110 may be disposed on the first via 120. The first bonding pad 110 may be disposed in the lower interlayer insulating film 180. The lower interlayer insulating film 180 and the first bonding insulating layer 140 may surround the first bonding pad 110. The first bonding insulating layer 140 may expose an upper surface 110_US of the first bonding pad 110. For example, a trench, which is formed in the lower interlayer insulating film 180 and the first bonding insulating layer 140, may be filled with a conductive material. The surface of the conductive material may be subject to a process to partially remove the excess conductive material until a first surface 140_A of the first bonding insulating layer 140 is exposed, and leaving only the remaining conductive material (the first bonding pad 110) in the trench. Accordingly, the upper surface 110_US of the first bonding pad 110 may be exposed with respect to the first bonding insulating layer 140, and the first bonding insulating layer 140 may not be disposed on the upper surface 110_US of the first bonding pad 110.

The second bonding pad 210 may be disposed on the second via 220. The second bonding pad 210 may be disposed in the upper interlayer insulating film 280. The upper interlayer insulating film 280 and the second bonding insulating layer 240 may surround the second bonding pad 210. The second bonding insulating layer 240 may expose a lower surface 210_BS of the second bonding pad 210. For example, similar to the process for forming the first bonding pad 110, the surface of a conductive material may be subject to a process until a third surface 240_A of the second bonding insulating layer 240 is exposed, thereby forming the second bonding pad 210. Accordingly, lower surface 210_BS of the second bonding pad 210 may be exposed with respect to the second bonding insulating layer 240, and the second bonding insulating layer 240 may not be disposed on the lower surface 210_BS of the second bonding pad 210.

The first bonding insulating layer 140 may include the first surface 140_A and a second surface 140_B opposite to the first surface 140_A. The first surface 140_A of the first bonding insulating layer 140 may be referred to as an upper surface of the first bonding insulating layer 140. In some embodiments, the first surface 140_A of the first bonding insulating layer 140 may be disposed on the same plane as the upper surface 110_US of the first bonding pad 110. However, the invention is not limited to the above.

The second bonding insulating layer 240 may include a third surface 240_A and a fourth surface 240_B opposite to the third surface 240_A. The third surface 240_A of the second bonding insulating layer 240 may be disposed on the first surface 140_A of the first bonding insulating layer 140. The third surface 240_A of the second bonding insulating layer 240 may be referred to as a lower surface of the second bonding insulating layer 240. In some embodiments, the third surface 240_A of the second bonding insulating layer 240 may be disposed on the same plane as the lower surface 210_BS of the second bonding pad 210. However, the invention is not limited to the above.

Each of the first bonding insulating layer 140 and the second bonding insulating layer 240 may include one of, for example, silicon carbonitride (SiCN), silicon nitride (SiN), silicon oxide carbonate (SiOC), silicon oxynitride (SiON), and silicon carbonate nitride (SiOCN).

The first bonding pad 110 may have a first width W1. The first width W1 of the first bonding pad 110 may be a width of the upper surface 110_US of the first bonding pad 110 in the horizontal direction. The second bonding pad 210 may have a second width W2. The second width W2 of the second bonding pad 210 may be a width of the lower surface 210_BS of the second bonding pad 210 in the horizontal direction. The second width W2 may be less than the first width W1. The second bonding pad 210 and the second bonding insulating layer 240 may be disposed on the upper surface 110_US of the first bonding pad 110. The lower surface 210_BS of the second bonding pad 210 may be in contact with the upper surface 110_US of the first bonding pad 110. For example, the second bonding pad 210 and the second bonding insulating layer 240 may cover the upper surface 110_US of the first bonding pad 110.The second bonding pad 210 may be disposed on a portion of the upper surface 110_US of the first bonding pad 110, and the second bonding insulating layer 240 may be disposed on the remaining area of the upper surface 110_US of the first bonding pad 110. The second bonding insulating layer 240 may be disposed on the remaining area of the upper surface 110_US of the first bonding pad 110, excluding the region where the second bonding pad 210 is disposed.

In some embodiments, each of the first and second widths W1 and W2 may be a maximum horizontal width of a corresponding one of the bonding surfaces 140_A and 240_A, when viewed in a top down view. The maximum horizontal widths may be measured in a plane extending parallel to the bonding interface between the first and second bonding insulating layers 140 and 240, and may be the largest value obtained by measuring the width in all directions across the plane extending parallel to the bonding interface between the first and second bonding insulating layers 140 and 240. One of the maximum horizontal widths W1 and W2 may be greater than the other.

Although the alignment keys (e.g., AK in FIG. 1) are used for alignment in the process of coupling the first circuit structure 10 and the second circuit structure 20, an error in the process may occur. According to some embodiments, since the first width W1 of the first bonding pad 110 is greater than the second width W2 of the second bonding pad 210, the first bonding pad 110 and the second bonding pad 210 may be properly coupled to each other even if the error occurs in the alignment of the first circuit structure 10 and the second circuit structure 20. Accordingly, electrical characteristics and reliability of the semiconductor device can be improved.

In some embodiments, the width of the first bonding pad 110 and the width of the second bonding pad 210 according to the vertical level may not be constant. For example, the width of the first bonding pad 110 may decrease as the distance from the upper surface 110_US of the first bonding pad 110 increases. The width of the second bonding pad 210 may decrease as the distance from the lower surface 210_BS of the second bonding pad 210 increases. However, the invention is not limited to the above. Unlike the illustration, the width of the first bonding pad 110 and the width of the second bonding pad 210 according to the vertical level may be constant.

In some embodiment, though not shown in the drawings, one of the first and second bonding pads 110 and 210 may have a less trapezoidal shape than the other from the perspective of a cross-sectional area. Accordingly, the bonding between the first and second bonding pads 110 and 210 may be less affected by potential misalignment that may occur therebetween. For example, the slope of the sidewall of one of the first and second bonding pads 110 and 210 may be greater (or steeper) than that of the other. The slope of the sidewall may be measured relative to the bonding interface between the first and second bonding insulating layers 140 and 240. For example, one of the first and second bonding pads 110 and 210 may have a trapezoidal shape from the perspective of a cross-sectional area such that a width gradually increases or decreases along a direction perpendicular to the bonding interface between the first and second bonding insulating layers 140 and 240. On the other hand, the width of the other of the first and second bonding pads 110 and 210 may be constant as the distance from the upper surface 110_US of the first bonding pad 110 increases.

The first bonding pad 110 may have an inclined side surface. For example, an angle between the upper surface 110_US and the side surface of the first bonding pad 110 may be an acute angle. The second bonding pad 210 may have an inclined side surface. For example, an angle between the lower surface 210_BS and the side surface of the second bonding pad 210 may be an acute angle. In some embodiments, the angle between the upper surface 110_US and the side surface of the first bonding pad 110 may be less than the angle between the lower surface 210_BS and the side surface of the second bonding pad 210. However, the invention is not limited to the above. The angle between the upper surface 110_US and the side surface of the first bonding pad 110 may be the same as the angle between the lower surface 210_BS and the side surface of the second bonding pad 210.

The first bonding pad 110 may have a first height H1. The first height H1 may refer to a distance from the upper surface 110_US of the first bonding pad 110 to the lower surface of the first bonding pad 110. The second bonding pad 210 may have a second height H2. The second height H2 may refer to a distance from the lower surface 210_BS of the second bonding pad 210 to the upper surface of the second bonding pad 210. The first height H1 and the second height H2 may be the same as each other. In another aspect, the first height H1 may be different from the second height H2.

Terms such as “same,” “equal,” “planar,” “coplanar,” “parallel,” and “perpendicular,” as used herein encompass identicality or near identicality including variations that may occur, for example, due to manufacturing processes. The term “substantially” may be used herein to emphasize this meaning, unless the context or other statements indicate otherwise.

The first bonding pad 110 may include a first pad barrier layer 110_B and a first pad filling layer 110_F. The first pad barrier layer 110_B may be disposed on a sidewall and a bottom surface of the first pad filling layer 110_F. The first pad filling layer 110_F may be disposed in the first pad barrier layer 110_B. The second bonding pad 210 may include a second pad barrier layer 210_B and a second pad filling layer 210_F. The second pad barrier layer 210_B may be disposed on a sidewall and a bottom surface of the second pad filling layer 210_F. The second pad filling layer 210_F may be disposed in the second pad barrier layer 210_B.

The first bonding pad 110 may include a first material. The second bonding pad 210 may include a second material different from the first material. Specifically, the first pad filling layer 110_F may include a first material, and the second pad filling layer 210_F may include a second material. For example, the first pad filling layer 110_F may include copper (Cu), and the second pad filling layer 210_F may include any one of cobalt (Co), tungsten (W), and molybdenum (Mo). The first pad barrier layer 110_B and the second pad barrier layer 210_B may include titanium (Ti), tantalum (Ta), and/or alloys thereof. A material of the first pad barrier layer 110_B may be the same as or different from a material of the second pad barrier layer 210_B.

The first via 120 may include a first via barrier layer 120_B and a first via filling layer 120_F. The first via barrier layer 120_B may be disposed on a sidewall and a bottom surface of the first via filling layer 120_F. The first via filling layer 120_F may be disposed in the first via barrier layer 120_B. The first via barrier layer 120_B may include the same material as the first pad barrier layer 110_B, and the first via filling layer 120_F may include the same material as the first pad filling layer 110_F.

The second via 220 may include a second via barrier layer 220_B and a second via filling layer 220_F. The second via barrier layer 220_B may be disposed on a sidewall and a bottom surface of the second via filling layer 220_F. The second via filling layer 220_F may be disposed in the second via barrier layer 220_B. The second via barrier layer 220_B may include the same material as the second pad barrier layer 210_B, and the second via filling layer 220_F may include the same material as the second pad filling layer 210_F.

The second height H2 of the second bonding pad 210 may be greater than the second width W2. For example, the second height H2 of the second bonding pad 210 may be four times or more than the second width W2. For example, the aspect ratio of the second bonding pad 210 may be 4 or more. If the second width W2 is 60 nm, the second height H2 may be 240 nm or more. In some embodiments, the second width W2 may be 10 nm to 120 nm. The aspect ratio of the trench for the second bonding pad 210 may be a ratio of the second height H2 to the second width W2. The aspect ratio of the trench for the first bonding pad 110 may be a ratio of the second height H1 to the second width W1. The aspect ratio of the trench for the second bonding pad 210 may be greater than the aspect ratio of the trench for the first bonding pad 110.

If a metal material is deposited in a trench having a high aspect ratio, a void may be formed in the metal material. For example, if a bonding pad is formed by depositing copper (Cu) in a trench with a high aspect ratio, a void may be formed in the bonding pad. On the other hand, the second bonding pad 210 according to some embodiments may be formed by a bottom-up method using any one of cobalt (Co), tungsten (W), and molybdenum (Mo). Accordingly, voids may not be formed in the second bonding pad 210 despite the second bonding pad 210 having a high aspect ratio. Accordingly, the second width W2 of the second bonding pad 210 may be formed to be smaller than the first width W1 of the first bonding pad 110, and reliability and integration density of the semiconductor device may be improved. For example, the bottom-up method may be a process in which the second pad filling layer 210_F is deposited or filled starting from the bottom (e.g., the narrower end rather than the wider end) of the trench and progressing upwards. The bottom-up method may ensure that the trench is completely filled from the base to the top (e.g., from the narrower end to the wider end). The bottom-up method may help to minimize defects such as voids or incomplete filling so as to fill the trench evenly from the bottom, rather than starting from the top and potentially leaving gaps or uneven distribution within the trench. In this paragraph, it will be understood that the terms “bottom,” “upwards,” “base,” and “top” are used to represent opposite orientations of those depicted in the figures, as if the device in the figures were turned over. For example, if the device in the figures is not turned over, these terms may be used differently, such that “top” would become “bottom.”

The first circuit structure 10 may be connected to the second circuit structure 20 by a direct bonding method. The direct bonding method may include direct bonding or connection of conductive components and direct bonding or connection of insulating components. For example, the upper surface 110_US of the first bonding pad 110 and the lower surface 210_BS of the second bonding pad 210 may be in contact each other, and an alloy may be formed on an interface between the first bonding pad 110 and the second bonding pad 210 such that the first bonding pad 110 and the second bonding pad 210 may be connected to each other. If the first bonding pad 110 includes copper (Cu) and the second bonding pad 210 includes cobalt (Co), a copper-cobalt (Cu-Co) alloy may be formed at the interface between the first bonding pad 110 and the second bonding pad 210. In addition, the first bonding insulating layer 140 and the second bonding insulating layer 240 may be coupled in direct contact with each other. For example, a compound bond may be formed between a constituent material of the first bonding insulating layer 140 and a constituent material of the second bonding insulating layer 240. The first bonding pad 110 and the second bonding pad 210 may be provided as an electrical connection path between the first circuit structure 10 and the second circuit structure 20.

The first circuit device 100 may include at least a part of a volatile memory device. For example, the first circuit device 100 may include a buried channel array transistor (BCAT), a vertical channel transistor, or at least a part of a dynamic random access memory (DRAM) of a vertical stack transistor structure.

The second circuit device 200 may include a circuit for performing a logical operation for controlling the operation of the first circuit device 100. The second circuit device 200 may include, for example, a sense amplifier that senses and amplifies data of a memory cell of the first circuit device 100, a word line driver that activates a word line of a selected row, etc., but the invention is not limited thereto.

In another aspect, the first circuit device 100 may include at least a part of a non-volatile memory device. For example, the first circuit device 100 may include at least a part of one of a NAND flash memory, a vertical NAND flash memory (vertical NAND), a NOR flash memory, a resistive random access memory (RRAM), a phase-change memory (PRAM), a magnetoresistive random access memory (MRAM), a ferroelectric random access memory (FRAM), a spin transfer torque random access memory (STT-RAM), and a combination thereof.

The second circuit device 200 may include a circuit for performing a logical operation for controlling the operation of the first circuit device 100. For example, the second circuit device 200 may include a row decoder that selects a row of memory cell arrays based on an address signal, a column decoder that selects a column of memory cell arrays based on an address signal, and a page buffer connected to the memory cell array through bit lines to read information stored in the memory cells, but the invention is not limited thereto.

In another aspect, the first circuit device 100 may include at least a part of a CMOS image sensor, and the second circuit device 200 may include a logic circuit for controlling the operation of the CMOS image sensor. In another aspect, each of the first circuit device 100 and the second circuit device 200 may include various passive elements such as capacitors, resistors, and inductors as well as various active elements such as transistors.

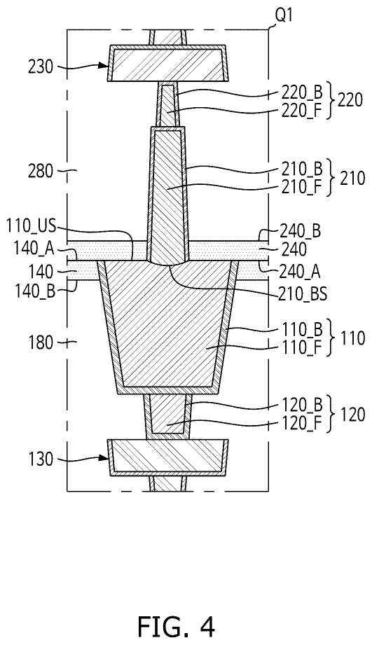

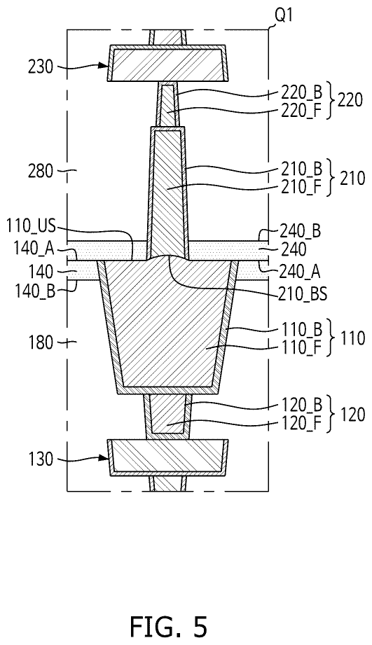

FIG. 4 is a diagram provided to explain a semiconductor device according to some embodiments. FIG. 5 is a diagram provided to explain a semiconductor device according to some embodiments. For reference, FIGS. 4 and 5 may correspond to an enlarged view provided to explain the region Q1 of FIG. 2. For convenience of description, different configurations from those described in FIGS. 2 and 3 will be mainly described.

Referring to FIGS. 4 and 5, in a semiconductor device according to some embodiments, an interface between the first bonding pad 110 and the second bonding pad 210 may include a curved surface.

The first bonding pad 110 may include a first material, and the second bonding pad 210 may include a second material different from the first material. The first material and the second material may have different coefficients of thermal expansion. Accordingly, the lower surface 210_BS of the second bonding pad 210 may not be disposed on the same plane as the third surface 240_A of the second bonding insulating layer 240.

As illustrated in FIG. 4, the interface between the first bonding pad 110 and the second bonding pad 210 may have a curved surface protruding toward the first bonding pad 110. The interface between the first bonding pad 110 and the second bonding pad 210 may be the lower surface 210_BS of the second bonding pad 210. From the perspective of a cross-sectional area, the lower surface 210_BS of the second bonding pad 210 may include a curved surface that is convex toward the first bonding pad 110.

In another aspect, as illustrated in FIG. 5, the interface between the first bonding pad 110 and the second bonding pad 210 may have a curved surface protruding toward the second bonding pad 210. For example, the lower surface 210_BS of the second bonding pad 210 may be a curved surface that curves inward toward the inside of the trench where the second bonding pad 210 is formed. From the perspective of a cross-sectional area, the lower surface 210_BS of the second bonding pad 210 may include a concave curve away from the first bonding pad 110.

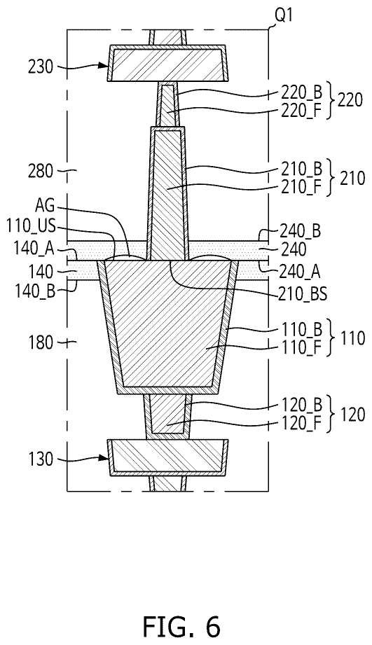

FIG. 6 is a diagram provided to explain a semiconductor device according to some embodiments. For reference, FIG. 6 may correspond to an enlarged view provided to explain the region Q1 of FIG. 2. For convenience of description, different configurations from those described in FIGS. 2 and 3 will be mainly described.

Referring to FIG. 6, the semiconductor device according to some embodiments may further include an air gap AG.

The air gap AG may be disposed between the first bonding pad 110 and the second bonding insulating layer 240. The air gap AG may be disposed on the upper surface 110_US of the first bonding pad 110. The air gap AG may have a convex shape, curving away from the upper surface 110_US of the first bonding pad 110 toward the second bonding insulating layer 240. When viewed in a plan view (in a top down view), the air gap AG may be disposed around a lower portion of the second bonding pad 210. The air gap AG may be referred to as a void. It should be appreciated that an “air gap” may comprise a gap having air or other gases (e.g., such as those present during manufacturing) or may comprise a gap forming a vacuum therein. The term “air” as discussed herein, may refer to atmospheric air, or other gases that may be present during the manufacturing process.

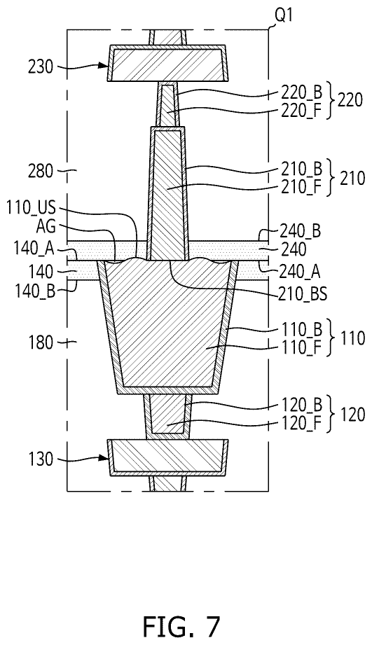

FIG. 7 is a diagram provided to explain a semiconductor device according to some embodiments. FIG. 7 may correspond to an enlarged view provided to explain the region Q1 of FIG. 2. For convenience of description, different configurations from those described in FIGS. 2 and 3 will be mainly described.

Referring to FIG. 7, in the semiconductor device according to some embodiments, the upper surface 110_US of the first bonding pad 110 may include a first region and a second region disposed around the first region.

The first region may be defined as a region where the upper surface 110_US of the first bonding pad 110 contacts the lower surface 210_BS of the second bonding pad 210. The second region may be defined as the remaining area of the upper surface 110_US of the first bonding pad 110, excluding the first region.

The upper surface 110_US of the first bonding pad 110 disposed in the first region may include a flat surface. However, the invention is not limited to the above. For example, as illustrated in FIG. 4 or FIG. 5, the upper surface 110_US of the first bonding pad 110 disposed in the first region may include a curved surface.

The upper surface 110_US of the first bonding pad 110 disposed in the second region may include a curved surface or a combination of a flat surface and a curved surface. In some embodiments, the air gap AG may be disposed on the second region. When viewed in a plan view, the air gap AG may be disposed around a lower portion of the second bonding pad 210.

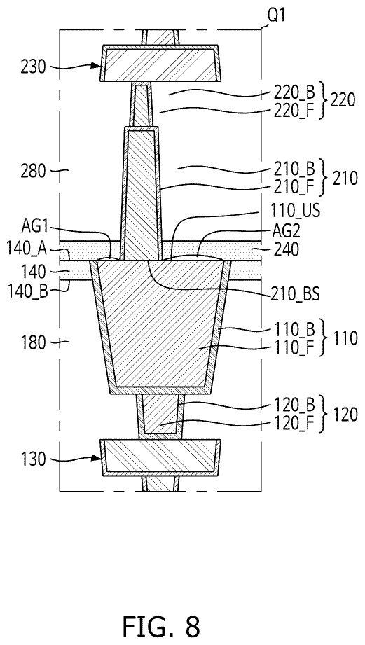

FIG. 8 is a diagram provided to explain a semiconductor device according to some embodiments. FIG. 8 may correspond to an enlarged view provided to explain the region Q1 of FIG. 2. For convenience of description, different configurations from those described in FIGS. 2 and 3 will be mainly described.

Referring to FIG. 8, the semiconductor device according to some embodiments may further include a first air gap AG1 and a second air gap AG2 disposed between the first bonding pad 110 and the second bonding insulating layer 240.

The second bonding pad 210 may be disposed on the first bonding pad 110. When viewed in a plan view, a center of the lower surface 210_BS of the second bonding pad 210 may be spaced apart from a center of the upper surface 110_US of the first bonding pad 110. For example, a distance from a first end of the first bonding pad 110 to the second bonding pad 210 in the horizontal direction may be different from a distance from a second end of the first bonding pad 110 to the second bonding pad 210 along a line extending in a plane extending parallel to the bonding interface between the first and second bonding insulating layers 140 and 240.

The first air gap AG1 and the second air gap AG2 may be disposed on the upper surface 110_US of the first bonding pad 110. The first air gap AG1 may be disposed in a region of the upper surface 110_US of the first bonding pad 110 where the distance from an end portion of the first bonding pad 110 to the second bonding pad 210 is shorter (relatively close). The second air gap AG2 may be disposed in a region of the upper surface 110_US of the first bonding pad 110 where the distance from the end portion of the first bonding pad 110 to the second bonding pad 210 is greater (relatively far).

The first air gap AG1 and the second air gap AG2 may expose the upper surface 110_US of the first bonding pad 110 to the atmosphere inside the air gaps. An area of the upper surface 110_US of the first bonding pad 110 exposed by the first air gap AG1 may be less than an area of the upper surface 110_US of the first bonding pad 110 exposed by the second air gap AG2. In some embodiments, a height of the first air gap AG1 may be less than a height of the second air gap AG2.

In some embodiments, each of the first air gap AG1 and the second air gap AG2 may be a part of a single air gap, which is disposed around a lower portion of the second bonding pad 210, when viewed in a plan view.

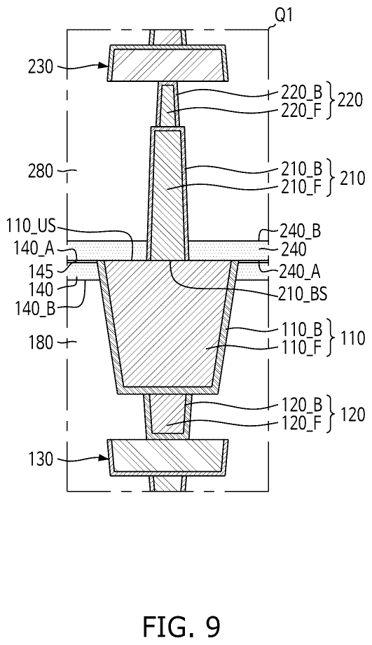

FIG. 9 is a diagram provided to explain a semiconductor device according to some embodiments. FIG. 9 may correspond to an enlarged view provided to explain the region Q1 of FIG. 2. For convenience of description, different configurations from those described in FIGS. 2 and 3 will be mainly described.

Referring to FIG. 9, the semiconductor device according to some embodiments may further include an insulating liner film 145 disposed between the first bonding insulating layer 140 and the second bonding insulating layer 240.

The insulating liner film 145 may be disposed between the upper surface of the first bonding insulating layer 140 and a lower surface of the second bonding insulating layer 240. The insulating liner film 145 may be disposed on the upper surface of the first bonding insulating layer 140 and may not be disposed on the upper surface 110_US of the first bonding pad 110. However, the invention is not limited to the above. For example, the insulating liner film 145 may be disposed between the upper surface 110_US of the first bonding pad 110 and the lower surface of the second bonding insulating layer 240. The insulating liner film 145 may include, for example, silicon oxide. For example, the insulating liner film 145 may serve as the plane (extending parallel to the bonding interface between the first and second bonding insulating layers 140 and 240) which is referenced when measuring the width and/or the distance as described above.

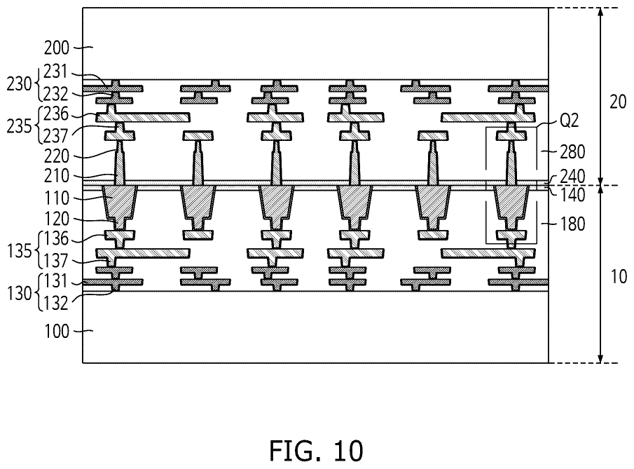

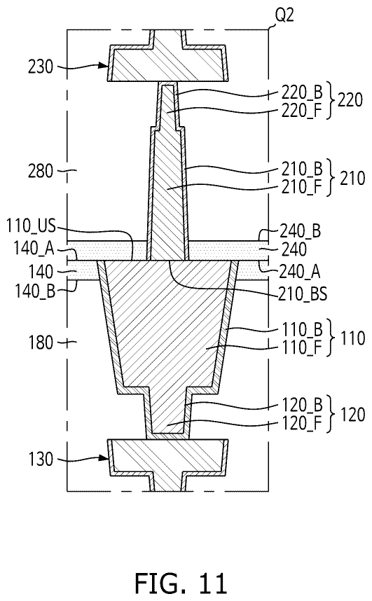

FIG. 10 is a diagram provided to explain a semiconductor device according to some embodiments. FIG. 11 is an enlarged view provided to explain a region Q2 of FIG. 10. For convenience of description, different configurations from those described in FIGS. 2 and 3 will be mainly described.

Referring to FIGS. 10 and 11, in the semiconductor device according to some embodiments, an interface between the first pad filling layer 110_F and the first via filling layer 120_F and an interface between the second pad filling layer 210_F and the second via filling layer 220_F may not be distinct.

The first pad filling layer 110_F may be disposed on the first via filling layer 120_F. Other components or material may not be disposed between the first via filling layer 120_F and the first pad filling layer 110_F. The interface between the first via filling layer 120_F and the first pad filling layer 110_F may not be distinguished. The first via barrier layer 120_B and the first pad barrier layer 110_B may be connected to each other.

In some embodiments, the first bonding pad 110 and the first via 120 may be formed by a single process. For example, a first trench for forming the first bonding pad 110 and the first via 120 may be formed in the lower interlayer insulating film 180 and the first bonding insulating layer 140. The first pad barrier layer 110_B and the first via barrier layer 120_B may be formed along a sidewall and a bottom surface of the first trench. The first via filling layer 120_F and the first pad filling layer 110_F may be formed in the first trench.

The second pad filling layer 210_F may be disposed on the second via filling layer 220_F. Other components or material may not be disposed between the second via filling layer 220_F and the second pad filling layer 210_F. The interface between the second via filling layer 220_F and the second pad filling layer 210_F may not be distinguished. The second via barrier layer 220_B and the second pad barrier layer 210_B may be connected to each other.

In some embodiments, the second bonding pad 210 and the second via 220 may be formed by a single process. For example, a second trench for forming the second bonding pad 210 and the second via 220 may be formed in the upper interlayer insulating film 280 and the second bonding insulating layer 240. The second pad barrier layer 210_B and the second via barrier layer 220_B may be formed along a sidewall and a bottom surface of the second trench. The second via filling layer 220_F and the second pad filling layer 210_F may be formed in the second trench.

In some embodiments, the process for forming the first lower interconnect layer 131 and the first lower via 132, the process for forming the second lower interconnect layer 136 and the second lower via 137, the process for forming the first upper interconnect layer 231 and the first upper via 232, and the process for forming the second upper interconnect layer 236 and the second upper via 237 may be substantially the same as or similar to each other. The respective interfaces of the interconnect layers and their corresponding vias may not be distinct

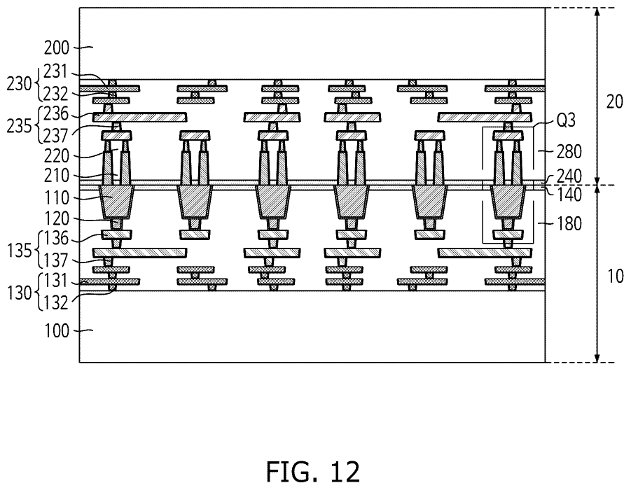

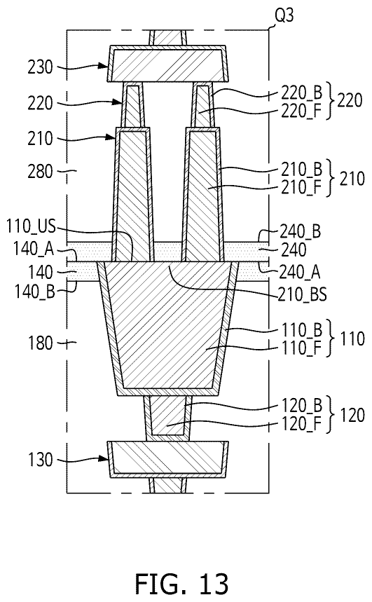

FIG. 12 is a diagram provided to explain a semiconductor device according to some embodiments. FIG. 13 is an enlarged view provided to explain a region Q3 of FIG. 12. For convenience of description, different configurations from those described in FIGS. 2 and 3 will be mainly described.

Referring to FIGS. 12 and 13, in the semiconductor device according to some embodiments, the number of first bonding pads 110 and the number of second bonding pads 210 may be different from each other.

A plurality of second bonding pads 210 may be coupled to the first bonding pad 110. The plurality of second bonding pads 210 may be disposed on one first bonding pad 110. For example, two second bonding pads 210 may be disposed on one first bonding pad 110. Although it is illustrated that the number of second bonding pads 210 coupled to one first bonding pad 110 is two, the number of second bonding pads 210 may vary.

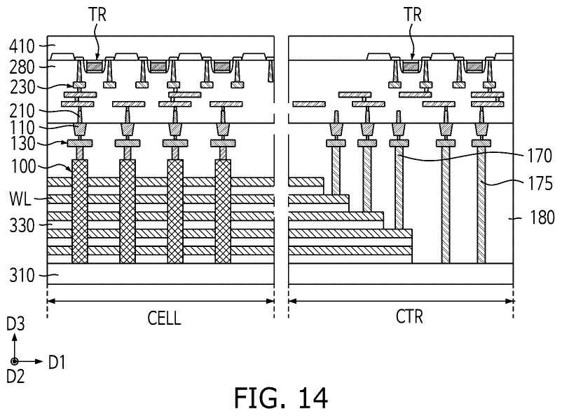

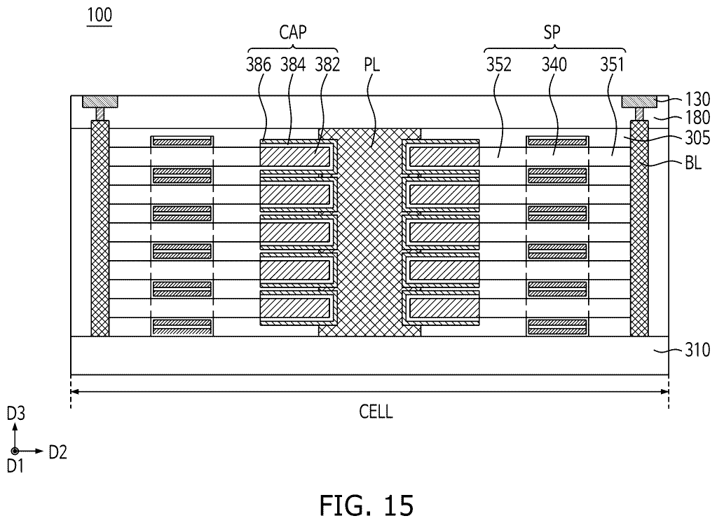

FIGS. 14 and 15 are diagrams provided to explain a semiconductor device according to some embodiments. For reference, FIG. 15 is a diagram provided to explain a cell region CELL of the first circuit device 100 of FIG. 14.

Referring to FIGS. 14 and 15, in the semiconductor device according to some embodiments, the first circuit device 100 may be at least a part of a memory device including a stacked channel. The first circuit device 100 may include a cell insulating film 305, a gate insulating film 330, a capacitor structure CAP, a cell semiconductor pattern SP, a word line WL, a plate electrode PL, and a bit line BL.

The cell semiconductor pattern SP may be disposed on the cell region CELL of the first circuit device 100. A plurality of cell semiconductor patterns SP and a plurality of cell insulating films 305 may be alternately stacked on an upper surface of a first substrate 310. The cell semiconductor pattern SP may have a shape of a line, a bar, or a column extending in the second direction D2. The cell semiconductor pattern SP may be formed through the word line WL.

For example, the cell semiconductor pattern SP may include silicon, germanium, silicon-germanium, indium gallium zinc oxide (IGZO), or indium tin zinc oxide (ITZO). In addition, for example, the cell semiconductor pattern SP may include a two-dimensional semiconductor material. The cell semiconductor pattern SP may include a cell channel pattern 340, a first source/drain pattern 351, and a second source/drain pattern 352.

The cell channel pattern 340 may be disposed between the first source/drain pattern 351 and the second source/drain pattern 352. The cell channel pattern 340 may be disposed between the word lines WL. In some embodiments, the word line WL may have a structure that completely surrounds the cell channel pattern 340. For example, the word line WL may have a gate-all-around structure.

The first source/drain pattern 351 may be disposed at one end of the cell channel pattern 340. The first source/drain pattern 351 may be connected to the bit line BL. The second source/drain pattern 352 may be disposed at the other end of the cell channel pattern 340. The second source/drain pattern 352 may be connected to the capacitor structure CAP.

The first source/drain pattern 351 and the second source/drain pattern 352 may have a first conductivity type (e.g., an n-type). The cell channel pattern 340 may not be doped or may have a second conductivity type (e.g., a p-type) different from the first conductivity type.

Each of a plurality of word lines WL may extend in the first direction D1 parallel to an upper surface of the first substrate 310. Each of the plurality of word lines WL may surround the cell channel pattern 340. The plurality of word lines WL may be disposed in the cell region CELL and the contact region CTR. The plurality of word lines WL on the contact region CTR may have a staircase shape. Each of the plurality of word lines WL may include a pad portion with an upper surface partially exposed due to the staircase shape. A lower contact via 170 may be connected to the pad portion of the word line WL.

The word line WL may include a conductive material. For example, the word line WL may include at least one of a doped semiconductor material, a conductive metal nitride, and a metal-semiconductor compound, but the invention is not limited thereto.

The gate insulating film 330 may be disposed between the cell channel pattern 340 and the word line WL. The gate insulating film 330 may surround the cell channel pattern 340. The word line WL may be disposed on the gate insulating film 330. The gate insulating film 330 may include at least one of a high-k insulating film, a silicon oxide film, a silicon nitride film, and a silicon oxynitride film.

The cell insulating film 305 may be disposed between the cell semiconductor patterns SP stacked in a third direction D3. A portion of the cell insulating film 305 may be disposed between the word lines WL adjacent to each other in the third direction D3. The cell insulating film 305 may electrically isolate the word lines WL. The cell insulating film 305 may include an insulating material.

The capacitor structure CAP may include a first electrode 382, a dielectric film 384, and a second electrode 386. The first electrode 382 may be disposed at one end of the cell semiconductor pattern SP. The first electrode 382 may be connected to the second source/drain pattern 352. The first electrode 382 may have a shape of a pillar extending in the second direction D2. The first electrode 382 may include at least one of a metal material, a metal nitride layer, and a metal silicide.

The dielectric film 384 may be disposed between the first electrode 382 and the second electrode 386. The dielectric film 384 may be disposed along a profile of the first electrode 382. For example, the dielectric film 384 may include at least one of silicon oxide, silicon nitride, silicon oxynitride, metal oxide, or a dielectric material having a perovskite structure.

The second electrode 386 may be disposed on the dielectric film 384. The second electrode 386 may extend along the dielectric film 384. The second electrode 386 may be connected to the plate electrode PL. For example, the second electrode 386 may include at least one of impurity-doped silicon, a metal material, a metal nitride layer, and a metal silicide. In some embodiments, the second electrode 386 may include substantially the same material as the first electrode 382.

The plate electrode PL may extend in the first direction D1 and the third direction D3. The plate electrode PL may be in contact with the second electrode 386. The plate electrode PL may be electrically connected to a plurality of second electrodes 386 disposed in the first direction D1. The plate electrode PL may include a conductive material. For example, the plate electrode PL may include one of a doped semiconductor material, a conductive metal nitride, a metal, and a metal-semiconductor compound.

The bit line BL may be disposed on the first substrate 310. The bit line BL may extend in the first direction D1. For example, the bit line BL may be formed through the plurality of stacked cell semiconductor patterns SP. The cell semiconductor patterns SP may be connected to the bit line BL. For example, the bit line BL may be electrically connected to the first source/drain pattern 351 of the cell semiconductor pattern SP.

The contact via 170 may be disposed in the lower interlayer insulating film 180. The contact via 170 may be formed through the lower interlayer insulating film 180 and disposed on the pad portion of the word line WL. The contact via 170 may be electrically connected to the word line WL through the pad portion. A through via 175 may be formed through the lower interlayer insulating film 180. The through via 175 may be connected to the first substrate 310.

The bit line BL, the contact via 170, and the through via 175 may be electrically connected to the lower interconnect structure 130. The lower interconnect structure 130 may be connected to the first bonding pad 110. The second bonding pad 210 may be disposed on the first bonding pad 110. The first bonding pad 110 may be directly bonded to the second bonding pad 210. For the first bonding pad 110 and the second bonding pad 210, the first bonding pad 110 and the second bonding pad 210 described with reference to FIGS. 1 to 13 may be applied.

The upper interlayer insulating film 280 may be disposed on the lower interlayer insulating film 180. The second bonding pad 210, the upper interconnect structure 230, a peripheral circuit transistor TR, and a second substrate 410 may be disposed in the upper interlayer insulating film 280.

The peripheral circuit transistor TR may be disposed on the second substrate 410. The peripheral circuit transistor TR may form a logic circuit for controlling the first circuit device 100. For example, the logic circuit may include various circuits including a command decoder, a control logic, an address buffer, a row decoder, a column decoder, a sense amplifier, a sub word line driver, a data input and output circuit, etc.

The peripheral circuit transistor TR may include a circuit gate dielectric layer, a circuit gate electrode, a spacer, and a source/drain region. The source/drain regions including impurities may be disposed on both sides of the circuit gate electrode. The spacers may be disposed on both sides of the circuit gate electrode.

The circuit gate dielectric layer may include silicon oxide, silicon nitride, or a high-k material. The circuit gate electrode may include at least one of titanium nitride (TiN), tantalum nitride (TaN), tungsten nitride (WN), titanium silicon nitride (TiSiN), tantalum silicon nitride (TaSiN), tungsten silicon nitride (WSiN), tungsten (W), copper (Cu), aluminum (Al), molybdenum (Mo), and ruthenium (Ru). The circuit gate electrode may include a semiconductor layer, for example, a doped polycrystalline silicon layer.

The upper interconnect structure 230 may be electrically connected to the circuit gate electrode and the source/drain region of the peripheral circuit transistor TR. For example, the upper interconnect structure 230 and the source/drain region may be electrically connected to each other through a source/drain contact.

Although it has been described herein that only the peripheral circuit transistor TR is disposed on the second substrate 410, the invention is not limited thereto. For example, not only various active elements such as transistors, but also various passive elements such as capacitors, registers, and inductors may be included on the second substrate 410.

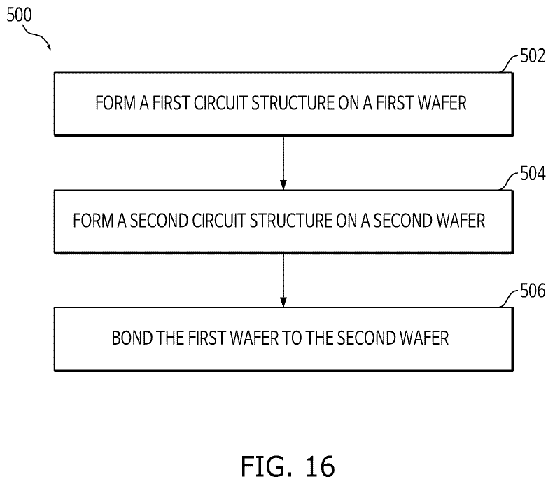

FIG. 16 is a flow diagram of an example of a method 500 of forming a semiconductor device according to an embodiment of the invention.

Referring to FIG. 16 and the description with reference to FIGS. 1 to 15, a semiconductor device may be formed by a wafer-to-wafer bonding process. The method 500 of FIG. 16 may be used to form the semiconductor device illustrated with reference to FIGS. 1 to 15.

The method 500 begins with forming first and second circuit structures on (or with) two wafers, at operations 502 and 504. Forming each of the first and second circuit structures may involve multiple processing steps, including the deposition, doping, and etching of various materials. The first and second circuit structures may be the structure indicated by 10 and 20 in the drawings above. After forming the first and second circuit structures, the wafers may be bonded together at operation 506. Bonding the wafers together may involve a wafer-to-wafer bonding technique to bond together the bonding pads described above.

In an embodiment, before the bonding, the wafers may be cleaned and/or the surfaces of the wafers may be activated (by surface treatments) to enhance the bonding. The cleaning and/or the surface treatments may be followed by the wafers being aligned to each other. The alignment key AK (described with reference to FIG. 1) may be used to align the wafers. For example, a first circuit structure and a first alignment key may be formed on (or with) a first semiconductor substrate, and a second circuit structure and a second alignment key may be formed on (or with) a second semiconductor substrate. The first semiconductor substrate and the second semiconductor substrate may be aligned using the first alignment key and the second alignment key, and the first circuit structure and the second circuit structure may be bonded to each other.

Although certain embodiments of the present disclosure have been described with reference to the accompanying drawings, those of ordinary skill in the art to which the present disclosure pertains will understand that the present invention may be implemented in other specific forms without changing its technical idea or essential features. Therefore, it should be understood that the embodiments described above are illustrative and non-limiting in all respects.

1. A semiconductor device, comprising:
a first bonding pad having a first width; and
a second bonding pad in contact with the first bonding pad and having a second width different from the first width,
wherein:
the first bonding pad comprises a first material, and
the second bonding pad comprises a second material different from the first material.

2. The semiconductor device according to claim 1, wherein
the first width is greater than the second width, and
the second material comprises any one of cobalt, tungsten, and molybdenum.

3. The semiconductor device according to claim 1, wherein
the second bonding pad has a first height, and
the first height is four times or more than the second width.

4. The semiconductor device according to claim 3, wherein
the first bonding pad has a second height, and
the first height is different from the second height.

5. The semiconductor device according to claim 3, wherein
the first bonding pad has a second height, and
the first height is the same as the second height.

6. The semiconductor device according to claim 1, wherein
an interface between the first bonding pad and the second bonding pad comprises a curved surface.

7. The semiconductor device according to claim 1, wherein a lower surface of the second bonding pad comprises a curved surface that is convex toward the first bonding pad.

8. The semiconductor device according to claim 1, wherein
the first bonding pad comprises a first pad barrier layer and a first pad filling layer, and
the second bonding pad comprises a second pad barrier layer and a second pad filling layer.

9. The semiconductor device according to claim 1, wherein an angle between an upper surface and a side surface of the first bonding pad is less than an angle between a lower surface and a side surface of the second bonding pad.

10. The semiconductor device according to claim 1, further comprising:
a first bonding insulating layer comprising a first surface and a second surface opposite to the first surface; and
a second bonding insulating layer comprising a third surface disposed on the first surface of the first bonding insulating layer and a fourth surface opposite to the third surface,
wherein:
the first bonding insulating layer surrounds at least a portion of the first bonding pad, and
the second bonding insulating layer surrounds at least a portion of the second bonding pad.

11. The semiconductor device according to claim 10, further comprising an air gap disposed between an upper surface of the first bonding pad and the second bonding insulating layer.

12. The semiconductor device according to claim 10, further comprising an insulating liner film disposed between the first bonding insulating layer and the second bonding insulating layer.

13. The semiconductor device according to claim 1, wherein
an upper surface of the first bonding pad comprises a first region in contact with a lower surface of the second bonding pad and a second region disposed around the first region, and
the second region of the upper surface of the first bonding pad comprises a curved surface.

14. The semiconductor device according to claim 1, further comprising:
a first via disposed on a lower surface of the first bonding pad; and
a second via disposed on an upper surface of the second bonding pad.

15. A semiconductor device, comprising:
a first sub-device comprising a first circuit layer and a first bonding pad disposed on the first circuit layer; and
a second sub-device disposed on the first sub-device and comprising a second circuit layer and a second bonding pad in contact with to the first bonding pad,
wherein:
the first bonding pad comprises a first material, and
the second bonding pad comprises a second material different from the first material.

16. The semiconductor device according to claim 15, further comprising:
a first connection wiring electrically connecting the first circuit layer to the first bonding pad; and
a second connection wiring electrically connecting the second circuit layer to the second bonding pad.

17. The semiconductor device according to claim 15, wherein a width of the first bonding pad is greater than a width of the second bonding pad.

18. The semiconductor device according to claim 15, wherein a width of the second bonding pad is less than a height of the second bonding pad.

19. The semiconductor device according to claim 15, wherein
the first material comprises copper, and
the second material comprises cobalt.

20. A semiconductor device, comprising:
a first sub-device comprising a first circuit layer, a first connection wiring electrically connected to the first circuit layer, and a first bonding pad electrically connected to the first connection wiring; and
a second sub-device electrically connected to the first sub-device,
wherein:
the second sub-device comprises a second circuit layer, a second connection wiring electrically connected to the second circuit layer, and a second bonding pad electrically connected to the second connection wiring and in contact with the first bonding pad,
the first bonding pad comprises a first material,
the second bonding pad comprises a second material different from the first material,
a width of the first bonding pad is greater than a width of the second bonding pad, and
the width of the second bonding pad is less than a height of the second bonding pad.
